(19) United States
(12) Patent Application Publication
(10) Pub. No.: US 2025/0372589 A1
(43) Pub. Date: Dec. 4, 2025

(54) System Including an Active Interposer and Method for Manufacturing the Same

(71) Applicant: Taiwan Semiconductor Manufacturing Company, Ltd., Hsinchu (TW)

(72) Inventors: Tze-Chiang Huang, Hsinchu (TW); Yun-Han Lee, Hsinchu (TW); King-Ho Tam, Hsinchu (TW); Yong Zhong, Hsinchu (TW); Yu-Hao Liu, Hsinchu (TW); Yen-Ming Chen, Hsinchu (TW)

(21) Appl. No.: 18/916,874

(22) Filed: Oct. 16, 2024

Related U.S. Application Data
(60) Provisional application No. 63/652,299, filed on May 28, 2024.

(51) Int. Cl. H01L 25/18; H01L 23/00; H01L 23/31; H01L 23/498

(52) U.S. Cl. CPC H01L 25/18; H01L 23/3128; H01L 23/49816; H01L 23/49827; H01L 24/16; H01L 24/24; H01L 2224/16225; H01L 2224/24226; H01L 2924/1436

(57) ABSTRACT

A system includes an active interposer and a plurality of semiconductor chips. The active interposer includes an interposer substrate, a semiconductor die, and a front-side redistribution layer (RDL). The semiconductor die is formed in the interposer substrate and includes a die substrate, an active die circuit, and a conductive layer. The active die circuit is fabricated over the die substrate and includes one or more active components. The conductive layer is connected to the active die circuit. The front-side RDL is connected to the conductive layer. The semiconductor chips are bonded to the front-side RDL. A method for manufacturing the system is also disclosed.

### CROSS-REFERENCE TO RELATED APPLICATION

The present application claims priority to U.S. Provisional Application No. 63/652,299, filed May 28, 2024, the contents of which are incorporated by reference herein in its entirety.

### BACKGROUND

Packaging technologies, such as three-dimensional integrated circuit (3D-IC) and chip-on-wafer-on-substrate (CoWoS) technologies, involve stacking semiconductor chips on top of each other and interconnecting the semiconductor chips by a passive interposer. This arrangement can enhance performance while reducing the surface area occupied by the semiconductor chip on the package substrate.

### BRIEF DESCRIPTION OF THE DRAWINGS

Aspects of the present disclosure are best understood from the following detailed description when read with the accompanying figures:

FIG. 1 is a schematic block diagram illustrating an exemplary system in accordance with various embodiments;

FIG. 2A is a schematic top view illustrating another exemplary system in accordance with various embodiments;

FIG. 2B is a schematic sectional view illustrating another exemplary system in accordance with various embodiments;

FIG. 3A is a schematic top view illustrating another exemplary system in accordance with various embodiments;

FIG. 3B is a schematic sectional view illustrating another exemplary system in accordance with various embodiments;

FIG. 4 is a schematic sectional view illustrating an exemplary semiconductor die connected between front- and back-side redistribution layers in accordance with various embodiments;

FIG. 5A is a schematic top view illustrating another exemplary system in accordance with various embodiments;

FIG. 5B is a schematic sectional view illustrating another exemplary system in accordance with various embodiments;

FIG. 6A is a schematic top view illustrating another exemplary system in accordance with various embodiments;

FIG. 6B is a schematic sectional view illustrating another exemplary system in accordance with various embodiments;

FIG. 7A is a schematic top view illustrating another exemplary system in accordance with various embodiments;

FIG. 7B is a schematic sectional view illustrating another exemplary system in accordance with various embodiments;

FIG. 8A is a schematic top view illustrating another exemplary system in accordance with various embodiments;

FIG. 8B is a schematic sectional view illustrating another exemplary system in accordance with various embodiments;

FIG. 9A is a schematic top view illustrating another exemplary system in accordance with various embodiments;

FIG. 9B is a schematic sectional view illustrating another exemplary system in accordance with various embodiments;

FIG. 10 is a flowchart illustrating exemplary operations of a method of manufacturing a system in accordance with various embodiments;

FIGS. 11A-11F are sectional views illustrating another exemplary method for manufacturing a system at intermediate stages in accordance with various embodiments; and

FIG. 12 is a schematic sectional view illustrating another exemplary system in accordance with various embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Systems and methods herein describe three-dimensional integrated circuit (3D-IC) technologies, chip-on-wafer-on-substrate (CoWoS) technologies, and other modern packing technologies that involve stacking semiconductor chips (also referred to as integrated circuits or semiconductor dies) on top of each other and interconnecting the semiconductor chips using a passive interposer. In one embodiment, a passive interposer connects one or more semiconductor chips, e.g., system-on-chip (SoC), to one or more semiconductor chips, e.g., memory device, such as high bandwidth memory (HBM) devices. For example, the passive interposer may include an interposer substrate, a front-side redistribution layer (RDL) over a top surface of the interposer substrate, a back-side RDL over a bottom surface of the interposer substrate, and a plurality of through-interposer vias (TIVs) connected between the front- and back-side RDLs.

Such a passive interposer can be inefficient as it, e.g., limits the number of HBM devices that may be connected to the SoC. For example, while the HBM devices nearer to the SoC may not cause considerable signal deterioration between them and the SoC, HBM devices farther away from the passive interposer may significantly degrade signal quality between them and the SoC. Systems and methods as described in certain examples herein mitigate this issue by interconnecting the SoC and the HBM devices using an active interposer. In certain embodiments, the active interposer includes a die circuit that performs a predetermined circuit function and that maintains, if not enhances, the integrity of signal transmission and reception between the SoC and the HBM devices.

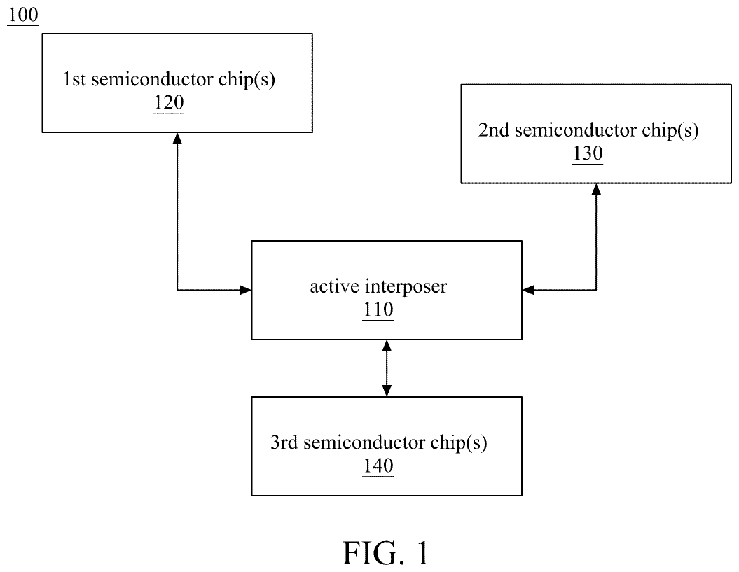

FIG. 1 is a schematic block diagram illustrating an exemplary system 100 in accordance with various embodiments of the present disclosure. As illustrated in FIG. 1, the example system 100 (e.g., a 3D-IC, a CoWoS, or other systems employing modern packing technologies) includes an active interposer 110 and a plurality of semiconductor chips 120-140 interconnected by the active interposer 110. In certain embodiments, the active interposer 110 includes an interposer substrate, one or more semiconductor dies, and a front-side RDL. Examples of materials for the interposer substrate include silicon, organic materials, glass, ceramics, polymer-based materials, other suitable interposer substrate materials, and combinations thereof.

A semiconductor chip may take a wide variety of forms. In one example, a semiconductor chip comprises a chip substrate, a chip circuit that is fabricated over the chip substrate and that performs a predetermined circuit function, and a conductive layer (e.g., a back end of line or BEOL) connected to the chip circuit. The chip circuit includes components, e.g., passive electronic components, such as resistors, capacitors, and inductors, as well as active electronic components, such as transistors, diodes, and integrated circuits.

The semiconductor die (also referred to herein as the local silicon interposer or LSI) includes a die substrate formed in the interposer substrate, a die circuit that is fabricated over the die substrate and that performs a predetermined circuit function, and a conductive layer (e.g., BEOL) connected to the die circuit. Examples of materials for the die substrate include silicon, silicon-on-insulator (SOI), gallium arsenide, silicon carbide, sapphire, germanium, gallium nitride, indium phosphide, and combinations thereof.

In one example, the die circuit includes active components (e.g., transistors, diodes, and integrated circuits) and/or passive components (e.g., resistors, inductors, and capacitors). The front-side RDL is connected between the conductive layer and the semiconductor chips 120-140. In certain embodiments, the active interposer 110 further includes a back-side RDL formed over the bottom surface of the interposer substrate and one or more through-interposer vias (TIVs) that interconnects the front- and back-side RDLs. In such certain embodiments, the semiconductor die (or LSI) further includes one or more through-substrate vias (TSVs) connected between the BEOL and the back-side RDL. Examples materials for the conductive layer, the RDLs, the TSVs, and the TIVs include copper, nickel, gold, silver, cobalt, tungsten, aluminum, other conductive materials, and combinations thereof.

The semiconductor chips 120-140 are bonded to the top surface and/or the bottom surface of the active interposer 110 and may include an SoC and a plurality of HBM devices. The SoC may include a central processing unit (CPU) that executes instructions and performs computations, an on-chip memory (e.g., random access memory or RAM, such as a static RAM or SRAM) that stores data and instructions, input/output (I/O) ports that is for communication with other devices (e.g., a universal serial bus or USB, a high-definition multimedia interface or HDMI, and other suitable interfaces), one or more peripherals each having a predetermined circuit function (e.g., a graphics processing unit or GPU, a digital signal processor or DSP, and the like), a power management circuit that manages power distribution across the chip, and other digital and/or analog components.

An HBM device is a type of dynamic RAM (DRAM) device, offers higher data transfer and lower power consumption by stacking DRAM dies vertically and interconnecting them using TSVs, thereby reducing space in a direction where such space is limited. In some embodiments, the semiconductor die or LSI of the active interposer 110 maintains or enhances communication (i.e., prevents signal degradation) between the SoC and the HBM devices. In such some embodiments, a relatively large number, e.g., more than four, of HBM devices can be connected to the SoC. In other embodiments, a portion of the SoC may be incorporated into the LSI of the active interposer 110. This approach conserves space within the SoC, allowing for the inclusion of additional circuitry, reduces power consumed by the SoC, and lowers a temperature of the SoC.

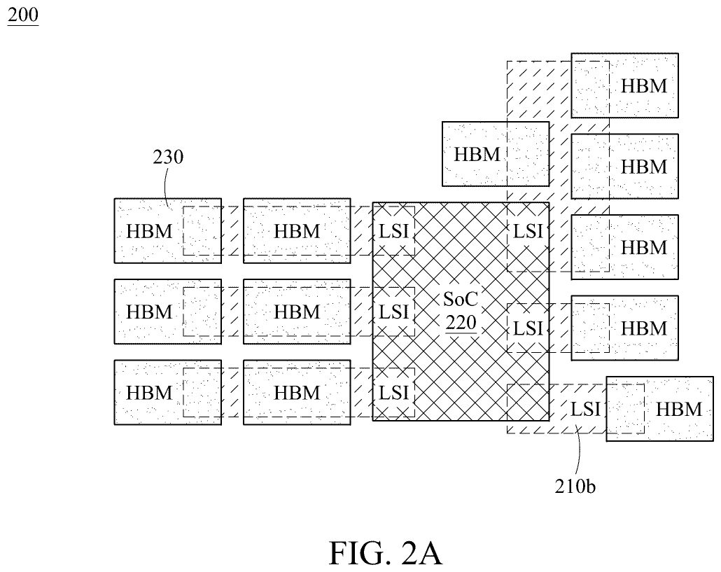

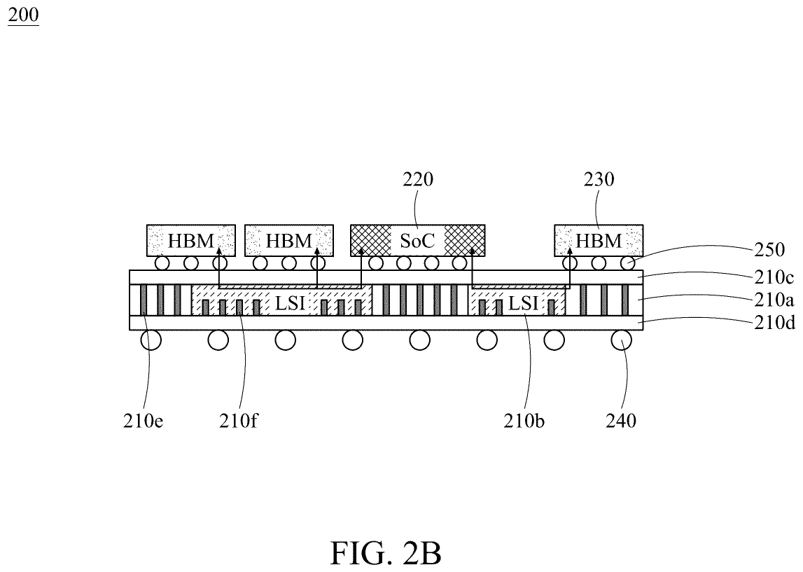

FIG. 2A is a schematic top view illustrating another exemplary system 200, e.g., system 100, in accordance with various embodiments of the present disclosure. FIG. 2B is a schematic sectional view illustrating another exemplary system, e.g., system 200, in accordance with various embodiments of the present disclosure. As illustrated in FIGS. 2A and 2B, the example system 200 includes an active interposer, e.g., active interposer 110, an SoC 220, and a plurality of HBM devices 230. The active interposer 110 includes an interposer substrate 210a, one or more semiconductor dies or LSIs 210b, first and second RDLs 210c, 210d, one or more TIVs 210e, and one or more TSVs 210f.

The LSI 210b includes a die substrate formed in the interposer substrate 210a, a die circuit, and a conductive layer (e.g., BEOL). The die circuit is fabricated over the die substrate, maintain or enhances signal integrity (e.g., data, instructions, control signals, and the like) by ensuring that signals are transmitted to subsequent stages without degradation, and includes buses, e.g., digital buses, such as buffer circuits, and connects the SoC 220 to the HBM devices 230. The first (or front-side) RDL 210c is disposed over the top surface of the interposer substrate 210a and connected between the LSI 210b and the semiconductor chips 220, 230. The second (or back-side) RDL 210d is disposed over the bottom surface of the interposer substrate 210a. The TIV 210e interconnects the front- and back-side RDLs 210c, 210d. The TSV 210f is connected between the BEOL and the back-side RDL 210d.

The active interposer 110 further includes a plurality of interconnects 240 that is formed over the back-side RDL 210c and that may be bonded to another semiconductor chip, a package substrate, or a printed circuit board (PCB). The semiconductor chip 220, 230 includes a plurality of interconnects 250 formed over the bottom surface thereof and bonded to the front-side RDL 210c. In certain embodiments, the interconnects 240, 250 are in the form of micro-bumps, solder balls, copper pillars, a ball grid array (BGA), a combination of metal and dielectric interconnects, other interconnects created by, e.g., hybrid bonding, tape-automated bonding (TAB), wire bonding, flip-chip bonding, other suitable interconnects, or combinations thereof.

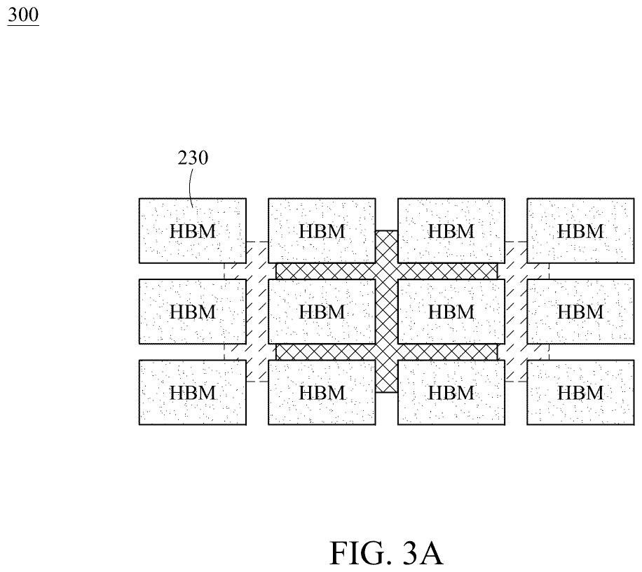

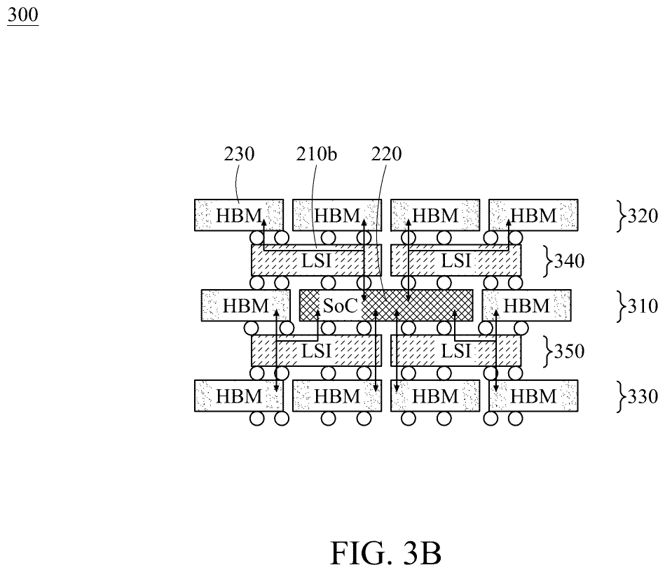

From the above description, the active interposer 110 may maintain or enhance the integrity of signal transmission and reception between the SoC 220 and the HBM devices 230. This allows for greater flexibility in the placement of the HBM devices 220 relative to the SoC 220 and with each other. Consequently, a relatively large number of HBM devices 230 can be bonded to the active interposer 110 and connected to the SoC 220. For example, FIG. 3A is a schematic top view illustrating another exemplary system 300, e.g., system 100, in accordance with various embodiments of the present disclosure. FIG. 3B is a schematic sectional view illustrating another exemplary system, e.g., system 300, in accordance with various embodiments of the present disclosure.

As illustrated in FIGS. 3A and 3B, the example system 300 differs from the system 200 in that the system 300 includes a plurality of semiconductor chip layers (e.g., semiconductor chip layers 310-330) and a plurality of active interposer layers 340, 350. For clarity, only the LSI 210b of the active interposer 110 is shown in FIG. 3B. The semiconductor chip layer 310 includes a SoC 220 and a pair of HBM devices 230, each of which is disposed on a respective one of the opposite sides of the SoC 220. The active interposer layer 340 is bonded to the top surface of the semiconductor chip layer 310 and includes one or more LSIs 210b, each connecting the HBM devices 230 to the SoC 220. Similarly, the active interposer layer 350 is bonded to the bottom surface of the semiconductor chip layer 310 and includes one or more LSIs 210b, each connecting the HBM devices 230 to the SoC 220. Additionally, the semiconductor chip layer 320 is bonded to the active interposer layer 340 and includes one or more HBM devices 230 interconnected by the LSIs 210b of the active interposer layer 340. Similarly, the semiconductor chip layer 340 is bonded to the active interposer layer 350 and includes one or more HBM devices 230 interconnected by the LSIs 210b of the active interposer layer 350.

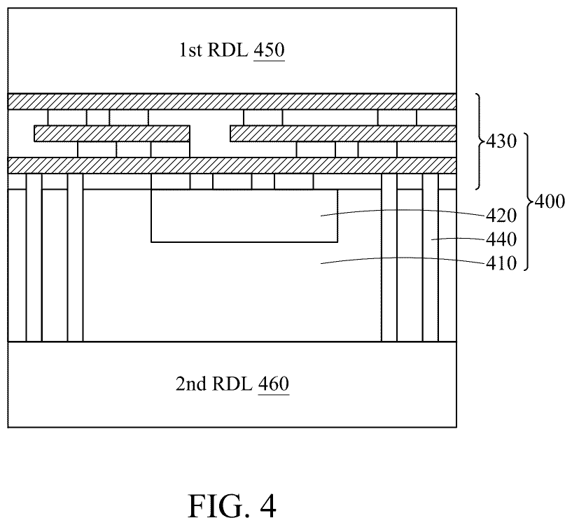

FIG. 4 is a schematic sectional view illustrating an exemplary LSI 400, e.g., LSI 210b, connected between front- and back-side RDLs 450, 460, e.g., front- and back-side RDLS 210c, 210d, in accordance with various embodiments of the present disclosure. As illustrated in FIG. 4, the example LSI (or semiconductor die) 400 includes a die substrate 410, a die circuit 420, a conductive layer (e.g., BEOL) 430, and one or more TSVs 440. Examples of materials for the die substrate 410 include silicon, silicon-on-insulator (SOI), gallium arsenide, silicon carbide, sapphire, germanium, gallium nitride, indium phosphide, and combinations thereof.

The die circuit 420 is fabricated over the die substrate 410, performs a predetermined circuit function, and includes active components (e.g., transistors, diodes, and/or integrated circuit) and passive components (e.g., resistors, inductors, and/or capacitors). The BEOL 430 is connected between the die circuit 420 and the front-side RDL 450, and includes horizontal and vertical metal lines. In certain embodiments, the passive components may be fabricated within the die circuit 420, the BEOL 430, or both. The TSV 440 interconnects the BEOL 430 and the back-side RDL 460. In certain embodiments, the RDL 450, 460, the BEOL 430, and the TSV 440 are made from copper, aluminum, tungsten, other conductive materials, or combinations thereof.

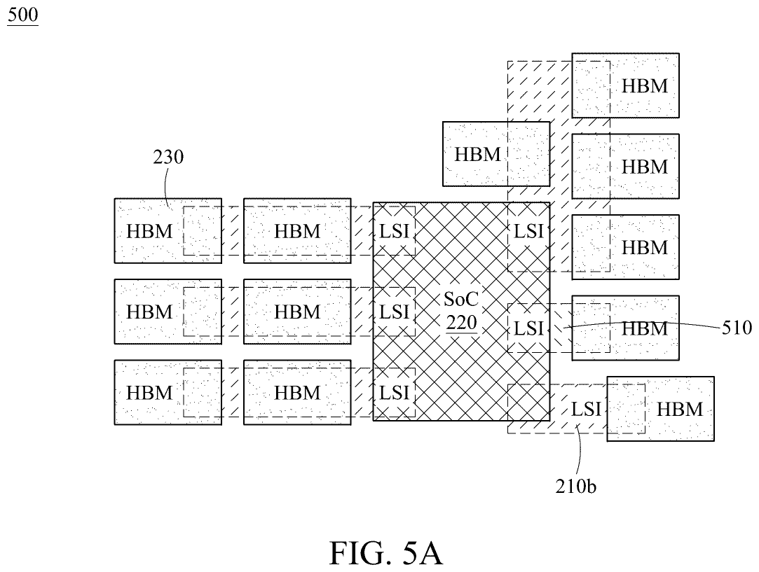

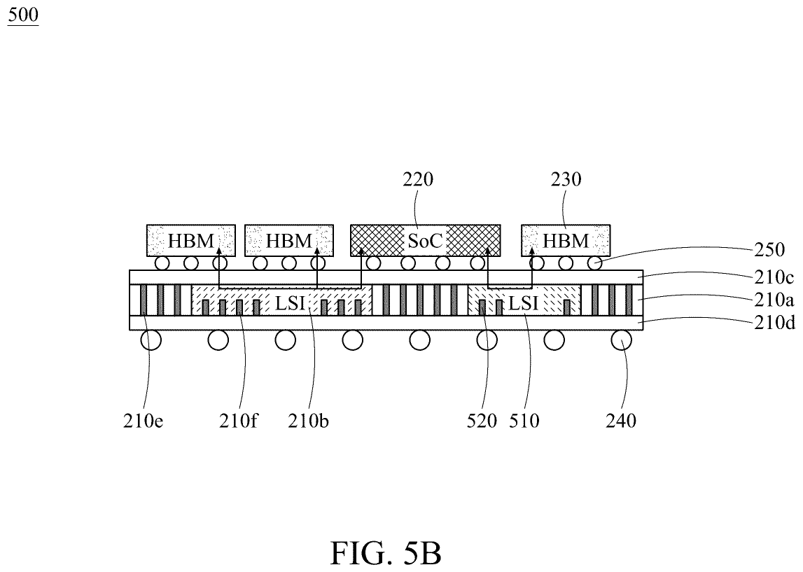

FIG. 5A is a schematic top view illustrating another exemplary system 500, e.g., system 100, in accordance with various embodiments of the present disclosure. FIG. 5B is a schematic sectional view illustrating another exemplary system, e.g., system 500, in accordance with various embodiments of the present disclosure. As illustrated in FIGS. 5A and 5B, the example system 500 differs from the previous embodiments in that the active interposer, e.g., active interposer 110, of the system 500 further includes at least one passive LSI 510. In this exemplary embodiment, the passive LSI 510 includes a die substrate, a die circuit, a conductive layer, and one or more TSVs 520. The die substrate of the passive LSI 510 is formed in the interposer substrate 210a. The die circuit is fabricated over the die substrate of the passive LSI 510. In this exemplary embodiment, the die circuit of the passive LSI 510 includes one or more passive components (e.g., resistors, inductors, and capacitors) and, unlike the active LSI 210b, does not include active components (e.g., transistors, diodes, and/or integrated circuits). The conductive layer (or BEOL) of the passive LSI 510 is connected between the die circuit of the passive LSI 510 and the front-side RDL 210c and includes horizontal and vertical metal lines. The TSV 520 of the passive LSI 510 interconnects the BEOL of the passive LSI 510 and the back-side RDL 210d. In certain embodiments, the passive components of the LSI 510 may be fabricated within the die circuit of the passive LSI 510, the BEOL of the passive LSI 510, or both.

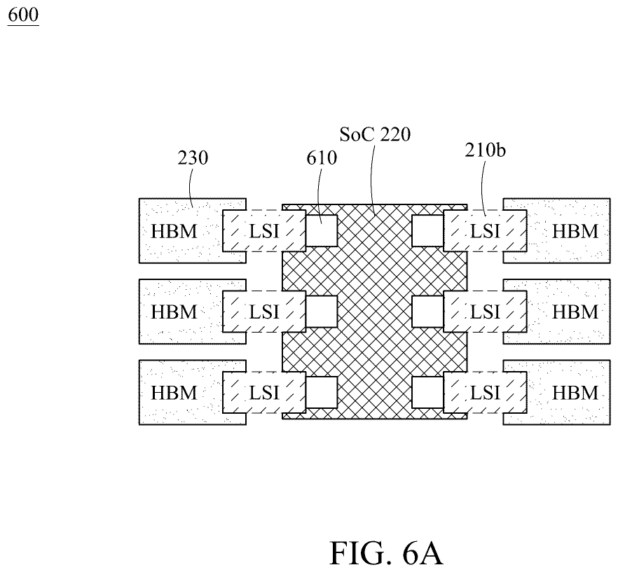

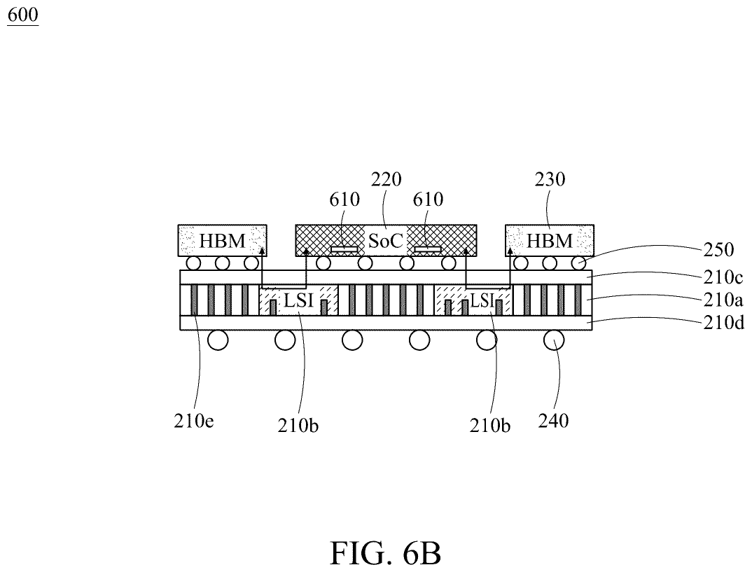

FIG. 6A is a schematic top view illustrating another exemplary system 600, e.g., system 100, in accordance with various embodiments of the present disclosure. FIG. 6B is a schematic sectional view illustrating another exemplary system, e.g., system 600, in accordance with various embodiments of the present disclosure. As illustrated in FIGS. 6A and 6B, the example system 600 differs from the previous embodiments in that the system 600 further includes one or more device circuits 610, e.g., memory controllers, such as die circuit 420. The memory controller 610 manages the operation of the HBM device 230. For example, the memory controller 610 has a portion formed in the SoC 220 and another portion formed in the active LSI 210b. In an alternative embodiment, the entire portion of the memory controller 610 is formed in the active LSI 210b. The construction as such of the system 600 conserves space within the SoC 220. This allows for the inclusion of additional circuitry in the SoC 220, reduces power consumed by the SoC, and lowers a temperature of the SoC. In certain embodiments, at least one of the active LSI 210b is dispensed with the memory controller 610.

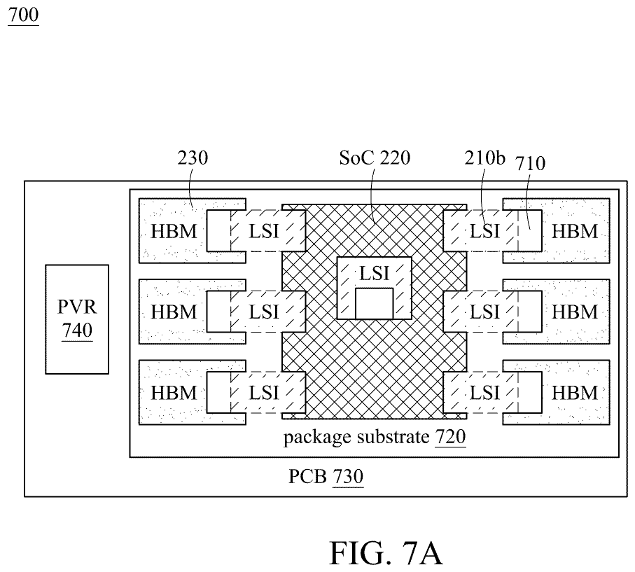

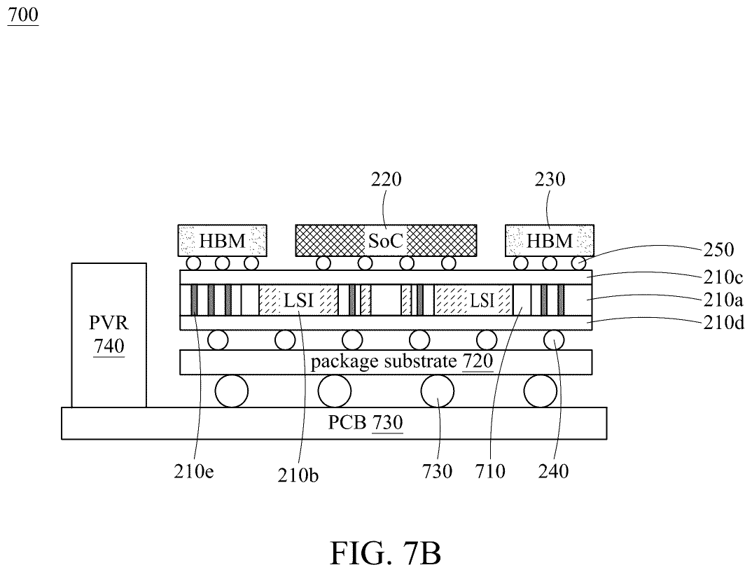

FIG. 7A is a schematic top view illustrating another exemplary system 700, e.g., system 100, in accordance with various embodiments of the present disclosure. FIG. 7B is a schematic sectional view illustrating another exemplary system, e.g., system 700, in accordance with various embodiments of the present disclosure. As illustrated in FIGS. 7A and 7B, the example system 700 differs from the previous embodiments in that the system 700 further includes one or more device circuits 710, e.g., integrated voltage regulator (IVR), such as die circuit 420. The IVR 710 generates a substantially constant output voltage regardless of fluctuations in an input voltage received thereby or variations in a load across thereof (e.g., the current drawn by the semiconductor chip 220, 230). In this exemplary embodiment, the IVR 710 is embedded in the active LSI 210b. In an alternative embodiment, a portion of the IVR 710 is formed in the SoC 220 and another portion of the IVR 710 is formed in the active LSI 210b. In certain embodiments, at least one of the active LSI 210b is dispensed with the IVR 710.

In some embodiments, the system 700 further includes a package substrate 720 that supports the assembly 110, 220, 230 thereon and that is mounted on a printed circuit board (PCB) 730. In such some embodiments, the system 700 further includes a package voltage regulator (PVR) 740 that is mounted on the PCB 730 and that powers semiconductor chips mounted on the PCB 730. In other embodiments, the system 700 does not include a PVR.

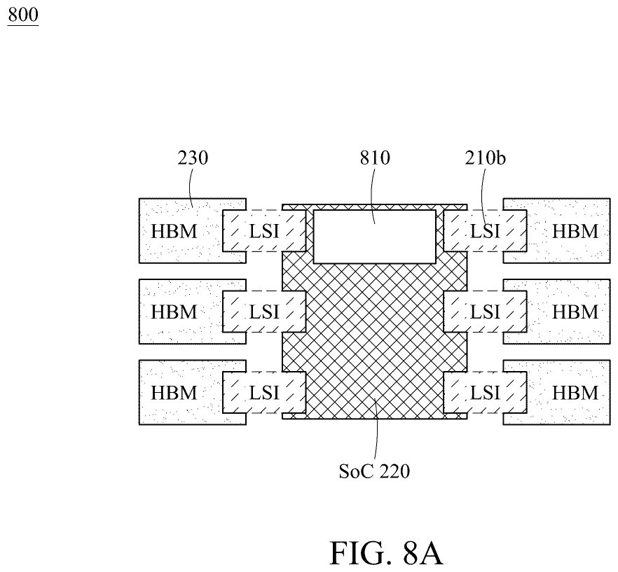

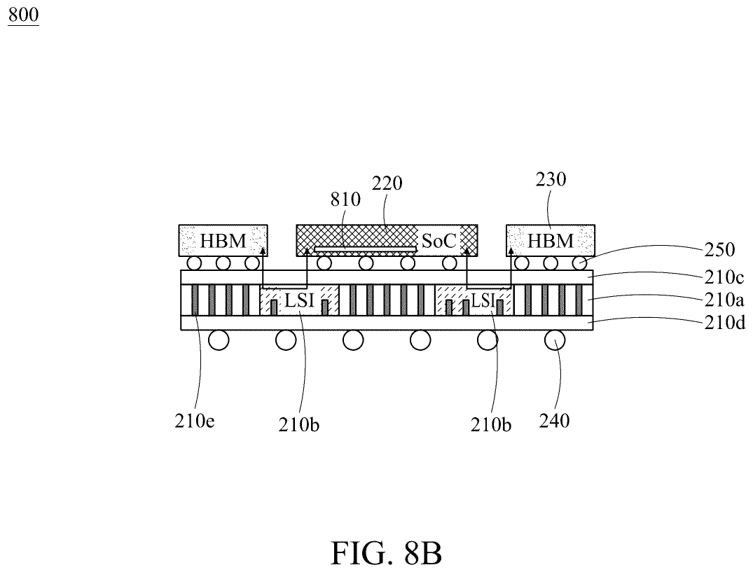

FIG. 8A is a schematic top view illustrating another exemplary system 800, e.g., system 100, in accordance with various embodiments of the present disclosure. FIG. 8B is a schematic sectional view illustrating another exemplary system, e.g., system 800, in accordance with various embodiments of the present disclosure. As illustrated in FIGS. 8A and 8B, the example system 800 differs from the previous embodiments, the system 800 further includes one or more device circuits 810, e.g., cache memory device, such as die circuit 420. The cache memory device 810 stores data frequently accessed by the SoC 220 from a main memory device (e.g., HBM device 230) to expedite data retrieval, minimizing latency and improving overall system 800 performance.

In certain embodiments, the cache memory device 810 has a portion formed in the SoC 220 and another portion formed in the active LSIs 210b. For example, the cache memory device 810 has different cache levels, such as level 1 (L1) cache, level 2 (L2) cache, and level 3 (L3) cache. The L1 cache has the smallest and fastest cache and may be located on the SoC 220, the active LSI 210b, or both. It has a capacity of, e.g., a few kilobytes (KB), and serves as the first level of data retrieval. The L2 cache is larger than L1 cache but is still relatively small and fast and may be located on the SoC 220, the active LSI 210b, or both. It has a capacity of larger than L1 cache, e.g., a few hundred kilobytes (KB) to a few megabytes (MB). The L3 cache is larger and slower than L1 and L2 caches, may be located on the SoC 810, the active LSI 210b, or both, and has a capacity of several megabytes (MB) to tens of megabytes (MB). It serves as a last-level cache before data is fetched from the main memory device, e.g., the HBM device 230.

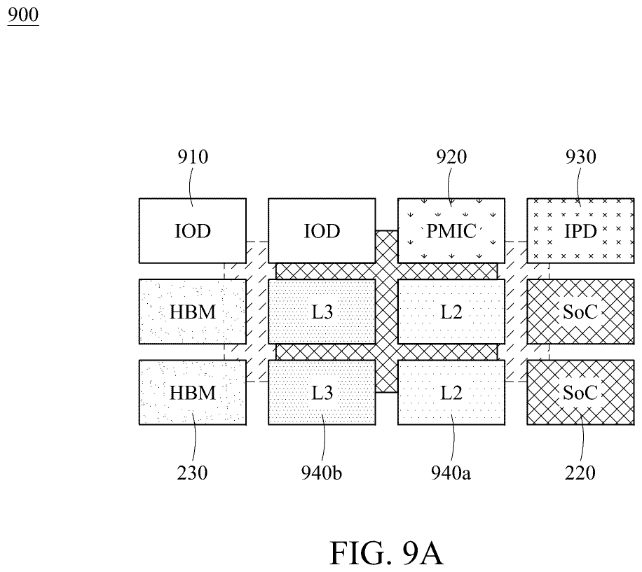

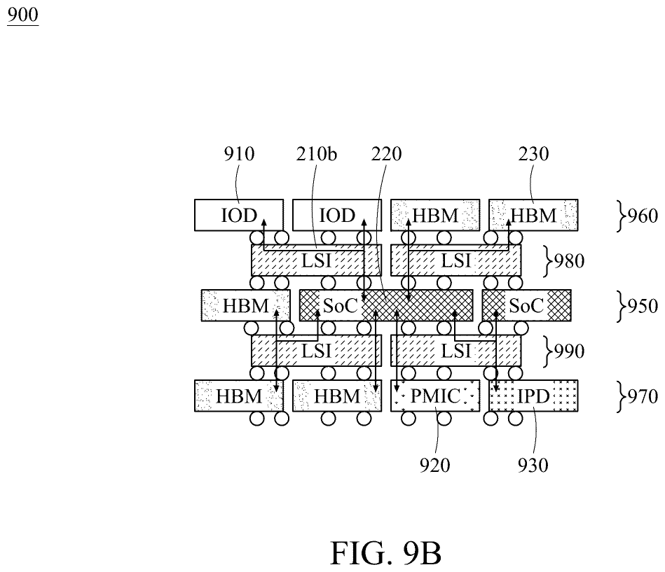

Although the system 100-300, 500-800 is exemplified with semiconductor chips including one SoC 220 and a certain number of HBM devices 230, it should be understood that, after reading this disclosure, the number of SoCs and HBM devices may be increased or decreased as desired and other types of semiconductor chips are contemplated in further embodiments. For example, FIG. 9A is a schematic top view illustrating another exemplary system 900, e.g., system 100, in accordance with various embodiments of the present disclosure. FIG. 9B is a schematic sectional view illustrating another exemplary system, e.g., system 900, in accordance with various embodiments of the present disclosure. As illustrated in FIGS. 9A and 9B, the example system 900 differs from the previous embodiments in that the system 900 includes a plurality of semiconductor chip layers 950-970 and a plurality of active interposer layers 980, 990. For clarity, only the LSI 210b of the active interposer 110 is shown in FIG. 9B.

In certain embodiments, the semiconductor chip layer 950 includes a pair of SoCs 220 and an HBM device 230. The active interposer layer 980 is bonded to the top surface of the semiconductor chip layer 950 and connects the semiconductor chips (e.g., one or more HBM devices 230 and one or more input/output devices or IODs 910) of the semiconductor chip layer 960 to the SoC 220. An IOD facilitates communication between the system 900 and devices external to the system 900, such as input devices (e.g., keyboard, mouse, scanner, microphone, and camera) and output devices (e.g., monitor, printer, and speaker).

Similarly, the active interposer layer 990 is bonded to the bottom surface of the semiconductor chip layer 910 and connects the semiconductor chips (e.g., one or more HBM devices 230, one or more power management integrated circuits or PMICs 920, and one or more integrated passive devices or IPDs 930) of the semiconductor chip layer 930 to the SoC 220. A PMIC manages power requirements (e.g., power distribution, power usage, voltage regulation, and protection features) of the system 900, whereas an IPD combines passive components (e.g., resistors, capacitors, and inductors) into a single package. In certain embodiments, the semiconductor chip layer 910-930 further includes one or more cache memory devices (e.g., L2 and/or L3 caches) 940a, 940b connected to the SoC 220 through the active interposer layer 980, 990.

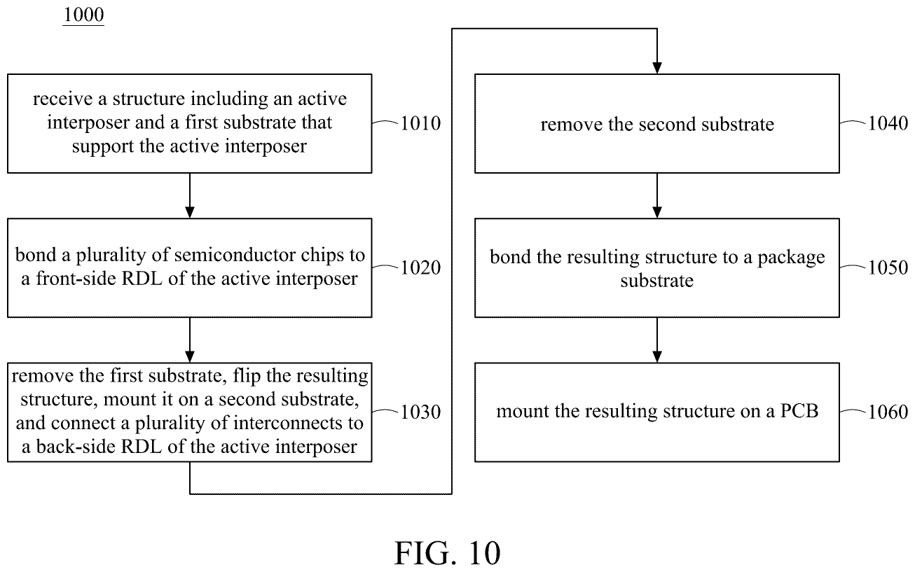

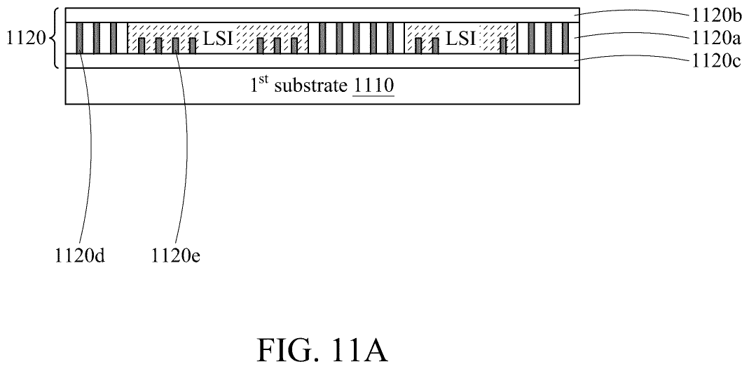

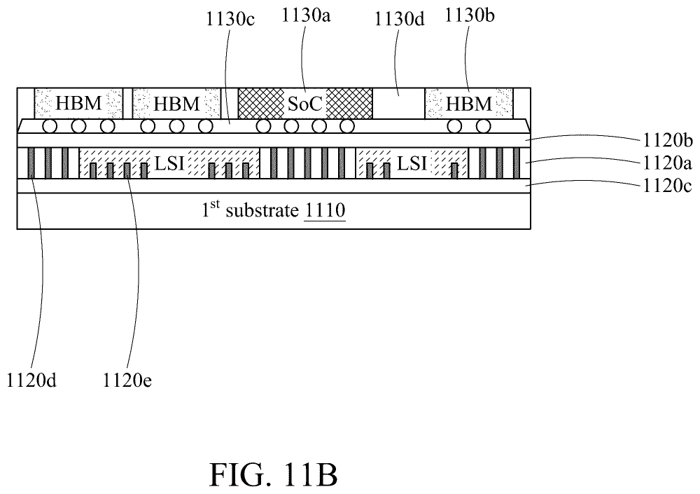

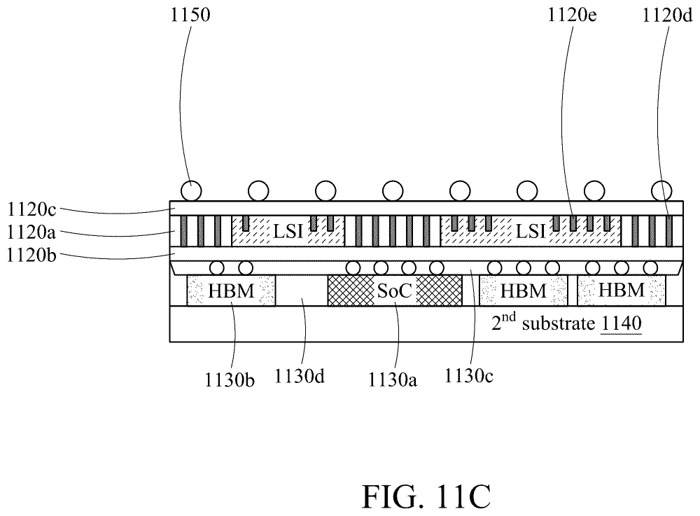

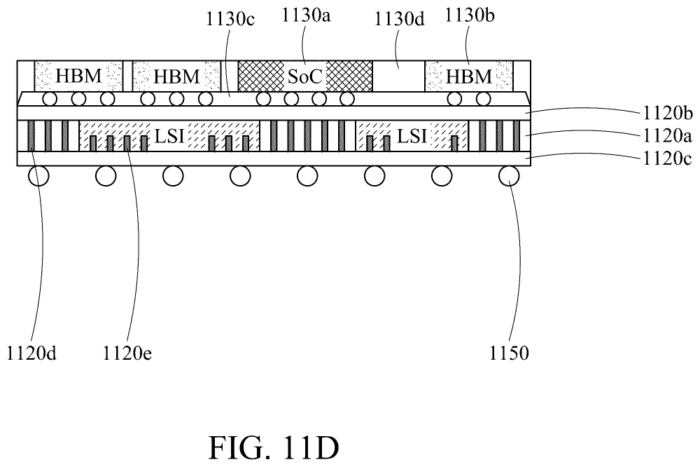

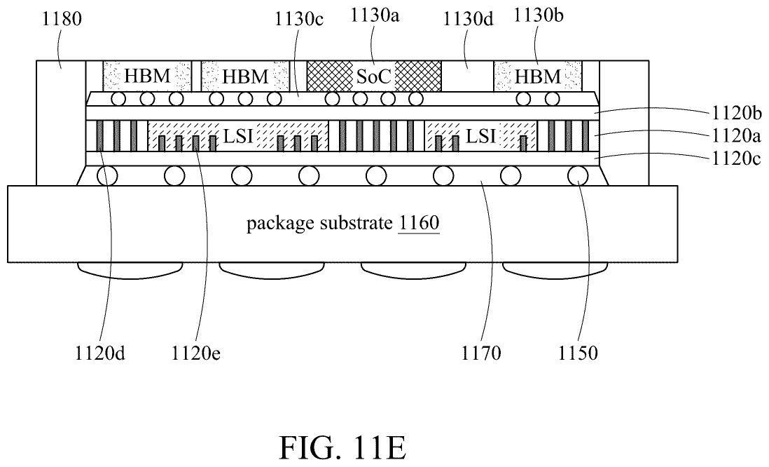

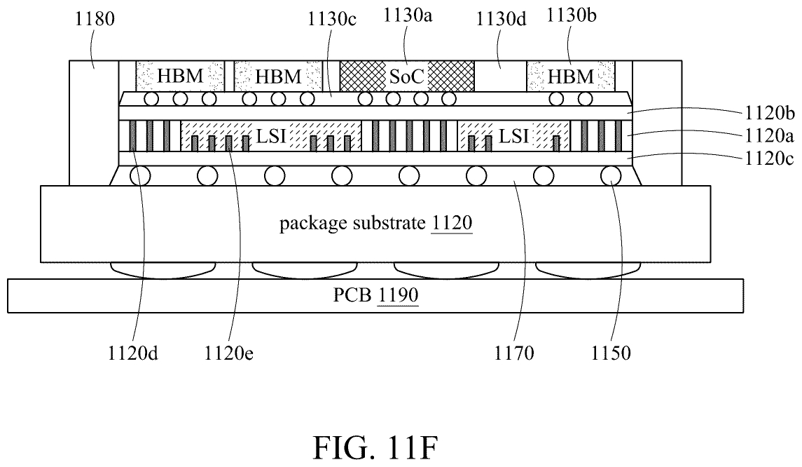

FIG. 10 is a flowchart illustrating exemplary operations of a method 1000 of manufacturing a system, e.g., system 100, 200, 300, 500-900, in accordance with various embodiments of the present disclosure. The example method 1000 will now be described with further reference to FIGS. 11A-11F for ease of understanding. FIGS. 11A-11F are sectional views illustrating another exemplary method, e.g., method 1000, for manufacturing a system, e.g., system 100, 200, 300, 500-900, at intermediate stages in accordance with various embodiments of the present disclosure. It is understood that the method 1000 is applicable to structures other than those of FIGS. 11A-11F. Further, it is understood that additional operations can be provided before, during, and after the method 1000, and some of the operations described below can be replaced or eliminated, in an alternative embodiment of the method 1000.

In operation 1010, as illustrated in FIG. 11A, the system manufacturing equipment receives a structure including a first substrate 1110 and an active interposer, e.g., active interposer 110, supported by the first substrate 1110. In certain embodiments, operation 1010 includes: receiving an interposer substrate 1120a, forming an LSI in the interposer substrate 1120a, forming a conductive layer (e.g., BEOL) over the LSI, connecting a front-side RDL 1120b to the conductive layer, forming a back-side RDL 1120c over the bottom surface of the interposer substrate 1120a, interconnecting the front- and back-side RDLs by one or more TIVs 1120d, and connecting the LSI to the back-side RDL 1120c using one or more TSVs 1120e.

In operation 1020, as illustrated in FIG. 11B, the system manufacturing equipment bonds a plurality of semiconductor chips, e.g., one or more SoCs 1130a and one or more HBM devices 1130b. In this exemplary embodiment, operation 1020 includes: forming an underfill 1130c between a top surface of the active interposer 110 and the bottom surface of the semiconductor chip 1130a, 1130b and forming a molding layer 1130d between the semiconductor chips 1130a, 1130b.

Subsequently, in operation 1030, as illustrated in FIG. 11C, the system manufacturing equipment removes the first substrate 1110 from the structure of FIG. 11B, flips the resulting structure, mounts it on a second substrate 1140, and connects a plurality of interconnects 1150 to the back-side RDL 1120c. In operation 1040, as illustrated in FIG. 11D, the system manufacturing equipment then removes the second substrate 1140 from the structure of FIG. 11C. Next, in operation 1150, as illustrated in FIG. 11E, the system manufacturing equipment bonds the structure of FIG. 11D to a package substrate 1160. In this exemplary embodiment, operation 1150 includes: the system manufacturing equipment forming an underfill 1170 between the bottom surface of the active interposer 110 and the top surface of the package substrate 1160 and a molding layer 1180 on opposite edges of the resulting structure. In an alternative embodiment, operation 1150 bonds the assembly of FIG. 11D to another semiconductor chip layer. Thereafter, in operation 1160, as illustrated in FIG. 11F, the structure of FIG. 11E is mounted on a PCB 1190.

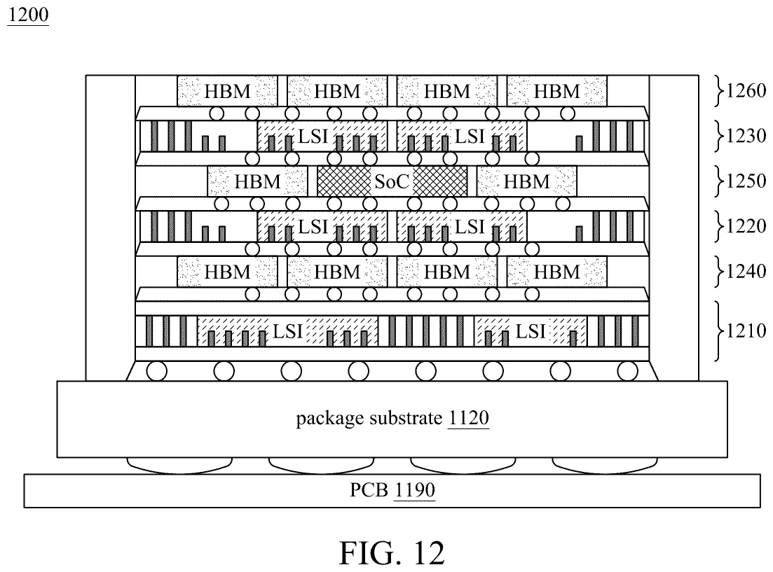

Although the system in FIGS. 11A-11F is exemplified with a single layer of active interposer and a single layer of semiconductor chips, it should be understood that, after reading this disclosure, the number of active interposer layers and/or the number of the semiconductor chip layers may be increased as desired. For example, FIG. 12 is a schematic sectional view illustrating another exemplary system, e.g., system 100, in accordance with various embodiments of the present disclosure. As illustrated in FIG. 12, the example system 1200 includes a plurality of active interposer layers 1210-1230 and a plurality of semiconductor chip layers 1240-1260. In this exemplary embodiment, the active interposer layers 1210-1230 and the semiconductor chip layers 1240-1260 are arranged alternately. In an alternative embodiments, the active interposer layers 1210-1230 and the semiconductor chip layers 1240-1260 may be arranged in other orders.

In an embodiment, a system comprises an active interposer and a plurality of semiconductor chips. The active interposer includes an interposer substrate, a semiconductor die, a front-side RDL, a back-side RDL, one or more TSVs, and one or more TIVs. The semiconductor die is formed in the interposer substrate and includes a die substrate, an active die circuit, and a conductive layer. The active die circuit is fabricated over the die substrate and includes one or more active components. The conductive layer is connected to the active die circuit. The front-side RDL is connected to the conductive layer. The back-side RDL is formed over a bottom surface of the interposer substrate. The TSV interconnect the conductive layer and the back-side RDL. The one or more TIVs are connected between the front- and back-side RDLs. The semiconductor chips are bonded to the front-side RDL.

In another embodiment, an interposer comprises an interposer substrate and a semiconductor die. The semiconductor die is formed in the interposer substrate and includes a die substrate, a passive die circuit, a conductive layer, and a front-side RDL. The passive die circuit is fabricated over the die substrate and includes one or more passive components. The conductive layer is connected to the passive die circuit. At least one of the passive die circuit and the conductive layer includes the one or more passive components. The front-side RDL is connected to the conductive layer.

In another embodiment, a method for manufacturing a system comprises fabricating an active interposer by: receiving an interposer substrate; providing a die substrate in the interposer substrate; fabricating over the die substrate an active die circuit that includes a plurality of active components; connecting a conductive layer to the active die circuit; forming a front-side RDL over the interposer substrate and connected to the conductive layer; and bonding a plurality of semiconductor chips to the front-side RDL.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A system comprising:
an active interposer comprising:
an interposer substrate;
a first semiconductor die formed in the interposer substrate and comprising:
a first die substrate;
an active die circuit fabricated over the first die substrate and comprising one or more active components; and
a first conductive layer connected to the active die circuit;
a front-side redistribution layer (RDL) connected to the first conductive layer;
a back-side RDL formed over a bottom surface of the interposer substrate;
one or more through-substrate vias (TSVs) interconnecting the first conductive layer and the back-side RDL; and
one or more through-interposer vias (TIVs) connected between the front- and back-side RDLs; and
a plurality of semiconductor chips bonded to the front-side RDL.

2. The system of claim 1, wherein the active die circuit is configured to maintain or enhance integrity of signal transmission and reception between the semiconductor chips.

3. The system of claim 1, further comprising a device circuit configured to perform a predefined circuit function, wherein the active die circuit includes a portion of the device circuit and another portion of the device circuit is embedded in the semiconductor chip.

4. The system of claim 3, wherein the device circuit includes at least one of a buffer circuit, an integrated voltage regulator (IVR), a memory device, and a memory controller.

5. The system of claim 1, further comprising one or more passive components, wherein the one or more passive components is within the active die circuit, the conductive layer, or both.

6. The system of claim 1, further comprising a second semiconductor die formed in the interposer substrate and comprising:
a second die substrate;
a passive die circuit formed over the second die substrate and comprising one or more passive components;
a second conductive layer connected between the passive die circuit and the front-side RDL, wherein the passive die circuit, the second conductive layer, or both include the one or more passive components; and
one or more TSVs interconnecting the second conductive layer and the back-side RDL.

7. The system of claim 1, wherein the semiconductor chips include at least one of a system-on-chip (SoC), a memory device, an integrated voltage regulator (IVR), an input/output device (IOD), a power management integrated circuit (PMIC), and an integrated passive device (IPD).

8. The system of claim 1, further comprising:
a plurality of active interposer layers; and
a plurality of semiconductor chip layers, wherein the active interposer layers and the semiconductor chip layer arranged on top of each other.

9. The system of claim 1, further comprising a package substrate, wherein a structure comprising the active interposer and the semiconductor chips is mounted on the package substrate.

10. An interposer comprising:
an interposer substrate; and
a semiconductor die formed in the interposer substrate and comprising:
a die substrate;
a passive die circuit fabricated over the die substrate and comprising one or more passive components;
a conductive layer connected to the passive die circuit, wherein at least one of the passive die circuit and the conductive layer includes the one or more passive components; and
a front-side redistribution layer (RDL) connected to the conductive layer.

11. The interposer of claim 10, further comprising a device circuit formed in the interposer substrate, configured to perform a predefined circuit function, and connected to the front-side RDL.

12. The interposer of claim 11, wherein the device circuit includes at least one of an integrated voltage regulator (IVR), a cache memory device, a memory controller, an input/output device (IOD), a power management integrated circuit (PMIC), and an integrated passive device (IPD).

13. The interposer of claim 11, wherein the interposer is configured for bonding semiconductor chips thereto.

14. The interposer of claim 10, further comprising:
a back-side RDL formed over a bottom surface of the interposer substrate;
one or more through-substrate vias (TSVs) interconnecting the conductive layer and the back-side RDL; and
one or more through-interposer vias (TIVs) connected between the front- and back-side RDLs.

15. A method for manufacturing a system, the method comprising:
fabricating an active interposer by:
receiving an interposer substrate;
providing a die substrate in the interposer substrate;
fabricating over the die substrate an active die circuit comprising a plurality of active components;
connecting a conductive layer to the active die circuit;
forming a front-side redistribution layer (RDL) over the interposer substrate and connected to the conductive layer; and
bonding a plurality of semiconductor chips to the front-side RDL.

16. The method of claim 15, wherein the active die circuit is configured to maintain or enhance integrity of signal transmission and reception between the semiconductor chips.

17. The method of claim 15, wherein the active die circuit includes at least one of a buffer circuit, an integrated voltage regulator (IVR), a memory device, and a memory controller.

18. The method of claim 15, wherein a portion of the active die circuit is embedded in at least one of the semiconductor chips.

19. The method of claim 15, further comprising:
forming a back-side RDL over a bottom surface of the active interposer;
connecting the active die circuit to the back-side RDL using one or more through-substrate vias (TSVs); and
connecting one or more through-interposer vias (TIVs) between the front- and back-side RDLs.

20. The method of claim 15, wherein the semiconductor chips include an input/output device (IOD), a memory device, a power management integrated circuit (PMIC), and an integrated passive device (IPD).
